(19) United States
(12) Patent Application Publication
(10) Pub. No.: US 2019/0107590 A1
(43) Pub. Date: Apr. 11, 2019

(54) DETECTION OF MATERIAL WITHIN A REGION OF THE EARTH USING NUCLEAR MAGNETIC RESONANCE

(71) Applicants: Eiichi Fukushima, Albuquerque, NM (US); Mark S. Conradi, Albuquerque, NM (US); Stephen A. Altobelli, Albuquerque, NM (US); Hans Thomann, Bedminster, NJ (US)

(72) Inventors: Eiichi Fukushima, Albuquerque, NM (US); Mark S. Conradi, Albuquerque, NM (US); Stephen A. Altobelli, Albuquerque, NM (US); Hans Thomann, Bedminster, NJ (US)

(21) Appl. No.: 16/131,444

(22) Filed: Sep. 14, 2018

Related U.S. Application Data
(60) Provisional application No. 62/570,977, filed on Oct. 11, 2017.

(51) Int. Cl. G01R 33/3415; G01V 3/14; G01R 33/44; G01R 33/483

(52) U.S. Cl. CPC G01R 33/3415; G01R 33/4838; G01R 33/445; G01V 3/14

(57) ABSTRACT

Provided are systems, methods, and apparatus for using nuclear magnetic resonance (NMR) to detect a first material in the presence of a second material within a region of the Earth and within a static magnetic field (such as Earth's magnetic field). These inventions are uniquely suited to detect NMR signals from materials remotely located from a measurement device (e.g., below ice with the device above the ice). They are further useful in detecting first material having relatively short spin-lattice (T1) relaxation time in the presence of second material having longer T1 relaxation time (and therefore slower response to applied magnetic fields). Two pre-polarization currents are used to create pre-polarization magnetic fields stronger than the static magnetic field, each applied over a period of time between the first material's T1 relaxation time and the second material's T1 relaxation time, enabling different ways to null the NMR signal from the second material.

### CROSS-REFERENCE TO RELATED APPLICATION

This application claims the benefit of U.S. Provisional Patent Application 62/570,977 filed Oct. 11, 2017 entitled DETECTION OF MATERIAL WITHIN A REGION OF THE EARTH USING NUCLEAR MAGNETIC RESONANCE, the entirety of which is incorporated by reference herein.

### FIELD OF THE INVENTION

The present disclosure relates generally to methods, systems, and apparatuses for the detection of a material within a region of the Earth. More particularly, it relates to Nuclear Magnetic Resonance (NMR) methods, systems, and apparatuses for detecting a material within a region of the Earth, such as detecting a minor amount of first material in a major amount of second material. The methods, systems, and apparatuses described herein may be particularly useful in, among other things, detecting a minor amount of hydrocarbon such as oil or gas within water.

### BACKGROUND OF THE DISCLOSURE

This section is intended to introduce various aspects of the art, which may be associated with one or more embodiments of the present disclosure. This discussion is believed to assist in providing a framework to facilitate a better understanding of particular aspects of the present disclosure. Accordingly, it should be understood that this section should be read in this light, and not necessarily as admissions of prior art.

NMR is frequently used to characterize the composition of various solids and liquids, frequently in a laboratory setting. NMR has more recently been adapted for some field uses, in particular in oil and gas production. For instance, NMR can be used to distinguish between a solid (e.g., rock in the Earth) and a liquid (e.g., ground water or oil). NMR molecular characterization works by placing a sample in a static magnetic field to align the net magnetization vector of the protons with the field. The proton magnetic moments are then perturbed using one or more radio frequency (RF) excitation signals. The energy released or emitted as these magnetic moments return to equilibrium (precession) is monitored by a receiver.

In analytical applications of NMR, where measurements are typically made in strong, homogeneous magnetic fields, the NMR signal of protons of one species of material (e.g., hydrocarbons such as oil, gas, or the like) are generally readily distinguished from those protons in other species of material (e.g., water), even where both materials are liquids, and even where significantly more of one material than the other is present. Such distinctions may be made, e.g., by observing small frequency differences in the resonance frequencies of the protons of such different materials.

However, Earth's magnetic field is much weaker (approx. 5 orders of magnitude weaker) than typical laboratory static magnetic fields, which means a corresponding reduction in the Larmor frequency for RF signals to be used in obtaining NMR measurements of protons within the magnetic field (e.g., from hundreds of MHz in laboratory settings, to about 2 kHz in the Earth's magnetic field). When operating with such low frequency signals, the frequency differences between protons of one species of material and another may be too small to detect a distinguishable difference in the materials in the resulting spectral display. The presence of the second material may affect the accuracy of measurements of the first material, for example by generating an NMR signal from the second material which masks a potential NMR signal from the first material. This could result in an interpretation of the NMR measurement which is known as a false positive measurement. The presence of the second material in excess compared to the first material(s) may result in the spectral band of the second material subsuming the spectral band of the first material and any other material(s).

These problems with Earth's-field NMR can pose great difficulty in using NMR for detecting the presence of a first material within or among a second material in many situations, particularly when there is a greater amount of second material than first material. For instance, in oil and gas operations, oil and/or gas production or transfer may be necessary in ice-prone marine or freshwater environments. Subsurface releases of oil and/or gas could occur in such operations and/or transfer (e.g., pipeline transfer)—for example, from a well blowout or leaking pipeline—resulting in oil and/or gas trapped within or beneath ice. Oil-spill countermeasures require that this oil is accurately located and mapped.

It would be to great advantage to be able to use NMR detection techniques to remotely and accurately identify the presence and/or location of hydrocarbons such as oil and/or gas within such environments. Such techniques could include suppressing the signal from the majority material (e.g., water) so as to leave only a signal indicating the presence of a minority material (e.g., hydrocarbons). We previously described one such approach in WIPO Publication WO 2015/084347. For instance, one technique described therein involves utilizing an inversion RF transmission (e.g., an adiabatic inversion) in combination with a read RF signal timed after the inversion such that the second (majority) material is suppressed in the read signal, a technique which may be referred to as “inversion nulling.”

Other references of potential interest along these and similar lines include U.S. Pat. Nos. 3,019,383; 4,022,276; 4,769,602; 4,868,500; 8,436,609; and 9,103,889; as well as the following non-patent literature: F. Bloch, Nuclear Induction, Phys. Rev. 70, 460-474 (1946); C. J. Hardy et al., Efficient Adiabatic Fast Passage for NMR Population Inversion in the Presence of Radiofrequency Field Inhomogeneity and Frequency Offsets, J. Magn. Reson. 66, 470-482 (1986); Gev, et al., Detection of the Water Level of Fractured Phreatic Aquifers Using Nuclear Magnetic Resonance (NMR) Geophysical Measurements, J. of Applied Geophysics 34, pp. 277-282 (1994); Slichter, Charles P., Principles of Magnetic Resonance, 2nd Edition Springer Series in Solid-State Sciences, (1996); M. Garwood and L. DelaBarre, The Return of the Frequency Sweep: Designing Adiabatic Pulses for Contemporary NMR, J. Magn. Reson. 153, 155-177 (2001); Legchenko, et al., Nuclear Magnetic Resonance as a Geophysical Tool for Hydrogeologists, J. of Applied Geophysics 50, pp. 21-46 (2002); Weichman, et al., Study of Surface Nuclear Magnetic Resonance Inverse Problems, J. of Applied Geophysics 50, pp. Mohnke, et al., Smooth and Block Inversion of Surface NMR Amplitudes and Decay Times Using Simulated Annealing, J. of Applied Geophysics 50, pp. 163-177 (2002); Shushakov, et al., Hydrocarbon Contamination of Aquifers by SNMR Detection, WM'04 Conference, Feb. 29-Mar. 4, 2004, Tucson, Ariz.

### SUMMARY OF THE DISCLOSURE

This disclosure presents distinct, more effective and more readily-implemented solutions than those currently known for detecting the presence of a first material within a second material within a region of Earth, in particular in situations wherein the amount of second material is substantially greater than the amount of first material. These solutions are particularly useful for detecting the presence of hydrocarbons such as oil and/or gas within water, particularly for detecting a minor amount of hydrocarbons within a major amount of water. However, one could readily apply these solutions to many other combinations of first and second materials within a region of the Earth; therefore, although some embodiments are directed to detecting the presence of hydrocarbons such as oil and/or gas within water, many other embodiments are not necessarily so limited.

Methods according to some aspects entail detecting whether a first material is present with a second material within a region of interest that is within a static magnetic field B₀. Such methods may include: acquiring a first NMR measurement within the region of interest, and determining the presence of the first material within the region of interest from the first NMR measurement as a first result.

In various aspects, the present disclosure describes various techniques for acquiring the first NMR measurement that utilize two separately applied pre-polarization currents to generate additional magnetic fields Bₚₚ₁ and Bₚₚ₂ within the region of interest, in order to detect whether a first material is present in a second material within the region of interest. The strength of each of the additional magnetic fields Bₚₚ₁ and Bₚₚ₂ is preferably greater than the static magnetic field B₀, and furthermore the direction of each field is preferably, but not necessarily, aligned with (e.g., parallel with or at least having a component parallel with) the direction of the static magnetic field B₀. A first RF signal is transmitted into the region of interest between the applications of the two pre-polarization currents; a second RF signal is transmitted into the region of interest after the application of the second pre-polarization current.

Accordingly, acquiring a first NMR measurement within the region of interest in various aspects of the present disclosure includes: (a) applying a first pre-polarization current for a first period of time τ_{polz1} to generate within the region of interest a first additional magnetic field Bₚₚ₁ that is greater than the static magnetic field B₀; (b) transmitting, after the applying (a), a first radio frequency (RF) signal into the region of interest; (c) applying, after the transmitting (b), a second pre-polarization current for a second period of time τ_{polz2} to generate within the region of interest a second additional magnetic field Bₚₚ₂ that is greater than the static magnetic field B₀; (d) transmitting, after the applying (c), a second RF signal into the region of interest; and (e) receiving an NMR signal from the region of interest.

The pre-polarization currents are applied over a first period of time T_{polz1} and a second period of time τ_{polz2}, respectively. Both τ_{polz1} and τ_{polz2} are greater that the spin-lattice relaxation time (T1 relaxation time) of the first material (i.e., the material the presence of which is sought to be determined), and less than T1 relaxation time of the second material. This allows techniques according to various embodiments herein to take advantage of the physical phenomenon that materials with shorter T1 relaxation time respond faster to an applied magnetization field—that is, the magnetization vector for a material with shorter T1 relaxation time will change faster than the magnetization vector of a material with longer T1 relaxation time.

For instance, in methods according to some embodiments, the first RF signal is an RF inversion signal, which inverts the magnetization (also known as the longitudinal magnetization) vector of a material composed of atoms which have a magnetic moment in the static magnetic field B₀ of the region of interest. The second RF signal is an RF inspection signal, which tips the magnetization vector of said material in the static magnetic field B₀ in the region of interest into the transverse (x,y) plane, where the (x,y) plane is orthogonal to the direction of the longitudinal magnetization. As the transverse magnetization vector returns to its equilibrium position within the static magnetic field, it generates the observable NMR signal (e.g., a free induction decay (FID) signal) received for generating an NMR measurement according to well-known systems, devices, and methods.

Advantageously, the RF inspection signal according to these embodiments is timed to be applied when the magnetization vector M₂ of the second material is null as described in more detail herein, such that the RF inspection signal does not tip the magnetization vector M₂ of the second material (there being no vector to tip).

In particular of these embodiments, the first period of time τ_{polz1} and the second period of time τ_{polz2} are substantially equal (e.g., such that 0.99<τ_{polz1}/τ_{polz2}<1.01, more preferably such that 0.999<τ_{polz1}/τ_{polz2}<1.001), although in yet other embodiments τ_{polz1} may be less than τ_{polz2}.

In yet other embodiments, the first and second RF signals are both RF inspection signals, and τ_{polz1} and τ_{polz2} are each different from one another—that is, the pre-polarization currents are applied over different time durations. Such methods may be referred to by the shorthand as “double acquisition” methods, and further include algebraic subtraction of the two NMR signals obtained following each of the two RF inspection signals, effectively resulting in nullifying the NMR signal from the second material (leaving only the signal from the first material, if present, such that an NMR signal following this procedure will indicate the presence of the first material).

In various embodiments (both in accordance with those summarized above and otherwise), the first material is a hydrocarbon such as oil and/or gas, preferably a liquid hydrocarbon such as oil, and the second material is water (e.g., freshwater or seawater). Methods of such embodiments may be useful for detecting whether oil is present within water in a region of interest in the Earth, wherein the static magnetic field B₀ is Earth's magnetic field. Accordingly, such methods may include acquiring a NMR measurement from a portion of a body of water (e.g., freshwater or seawater), and, based at least in part on the acquired NMR measurement, determining whether oil is present in the portion of the body of water. Acquiring the NMR measurement may include substantially the actions for acquiring NMR measurements summarized above.

The portion of the body of water may in some embodiments be located under ice, or otherwise inaccessible for visual inspection. Such methods may be particularly useful, e.g., for identifying the presence of oil within water as part of oil spill recovery efforts.

### BRIEF DESCRIPTION OF THE DRAWINGS

FIG. 1 is a stylized current timing diagram with associated charts showing expected magnetic response, for purposes of illustrating techniques in accordance with some embodiments.

FIG. 2 is a stylized current timing diagram used to illustrate techniques in accordance with yet further embodiments.

FIG. 3 is a stylized chart illustrating magnitude of magnetization vectors generated in response to applied pre-polarization currents in accordance with some embodiments herein, referenced for purposes of illustrating techniques in accordance with some embodiments.

FIG. 4 is a timing diagram showing magnetic field strength and magnitude of magnetization vectors in connection with Example 1.

FIGS. 5A and 5B are NMR spectra in connection with Example 1.

FIG. 6 is illustrates signals from three NMR experiments superimposed onto a single spectrum in connection with Example 2.

### DETAILED DESCRIPTION OF THE INVENTION

### Definitions

The static magnetic field herein is referenced to have direction along the z-axis of an x,y,z vector space. Thus, reference to the “z-direction” means along the direction of the static magnetic field B₀. The positive or plus (+) z direction is in the direction with the static magnetic field B₀; the negative (−) z direction is opposite (i.e., 180° rotated from) the direction of the static magnetic field B₀. For those skilled in the art, the magnetization along the z direction may commonly be referred to as the longitudinal magnetization.

A “magnetization vector” of a material refers to the net magnetization vector of the protons in the material that respond to an external magnetic field, as would be recognized by those skilled in the art of NMR.

A “radio frequency inversion signal” or “RF inversion signal” refers to the transmission of radio waves into a region of interest such that the magnetization vector of material in the region of interest (and within the static magnetic field B₀) is inverted from the +z direction to the −z direction (e.g., a 180° change in direction of the vector). RF inversion signals include, e.g., inversion pulses or hard inversion pulses, adiabatic fast passage inversion sweeps, and/or continuous wave (CW) inversion signals.

A “radio frequency inspection signal” or “RF inspection signal” refers to the transmission of radio waves into a region of interest such that a temporary transverse magnetic field B₁ is generated in the region of interest (e.g., a field with direction in the (x,y) plane transverse to the z-axis direction of the static field B₀). This field tips the magnetization vector M of material in the region of interest into the transverse (x,y) plane, and preferably such that it has substantially 0 magnitude in the z-direction. As is known in the art, such non-equilibrium magnetization vectors precess about the z-axis (i.e., the direction of the static magnetic field B₀) as they return to their equilibrium state (oriented with the static magnetic field B₀), generating the observable NMR signal as they do so (e.g., a free induction decay (FID) signal). The observable NMR signal is received for generating an NMR measurement according to well-known systems, devices, and methods. RF inspection signals include, e.g., inspection pulses or hard pulses, adiabatic fast passage inspection sweeps, and/or continuous wave (CW) inspection signals.

The term “adiabatic fast passage” (AFP) (also referred to as “adiabatic rapid passage”) refers to a NMR technique which uses RF excitation signals that sweep a range of frequencies or a range of static magnetic field strengths during the signal transmission. The excitation signal is longer in duration as compared to a hard pulse and shorter in duration as compared to a continuous wave (CW). AFP is distinguished from, and not considered, a “hard” pulse or a CW technique. AFP excitation signals described in embodiments contained herein may refer to a frequency sweep occurring to generate the AFP excitation signal, but it is understood that a sweep of static magnetic field strengths may also be applied. It is also understood that a phase-modulated sweep may also be used. The general concept of AFP excitation used here also includes an embodiment comprised of a combination of frequency sweep and phase modulation of the RF excitation signal.

In one or more embodiments, the peak amplitudes of the AFP excitation signal may be substantially constant throughout the signal, for example the peak amplitude may be maintained at a desired value for at least 80%, 90%, 99%, or more of the signal. During the beginning and end of the AFP excitation sweep, the peak amplitudes of the RF frequency may be lower than the desired maximum peak amplitude. This occurs as a natural response function of the RF power transmitter and the response function of the RF coil circuitry, as discussed in further detail below.

In one or more embodiments, the peak amplitudes of the RF signal within the AFP sweep may have a well-defined time dependence as the RF frequency is swept between the upper and lower values of RF frequencies contained within the sweep. For example, when the amplitude is increased, a sinusoidal ramp may be used and when the amplitude is decreased, a co-sinusoidal ramp may be used. The excitation signal may have amplitude values less than the desired value at the beginning and end of the signal. In one or more embodiments, both the applied magnetic field B₁ resulting from the RF excitation peak amplitudes and the rate of the frequency sweep may be modulated to rotate the effective B₁ in a circular arc.

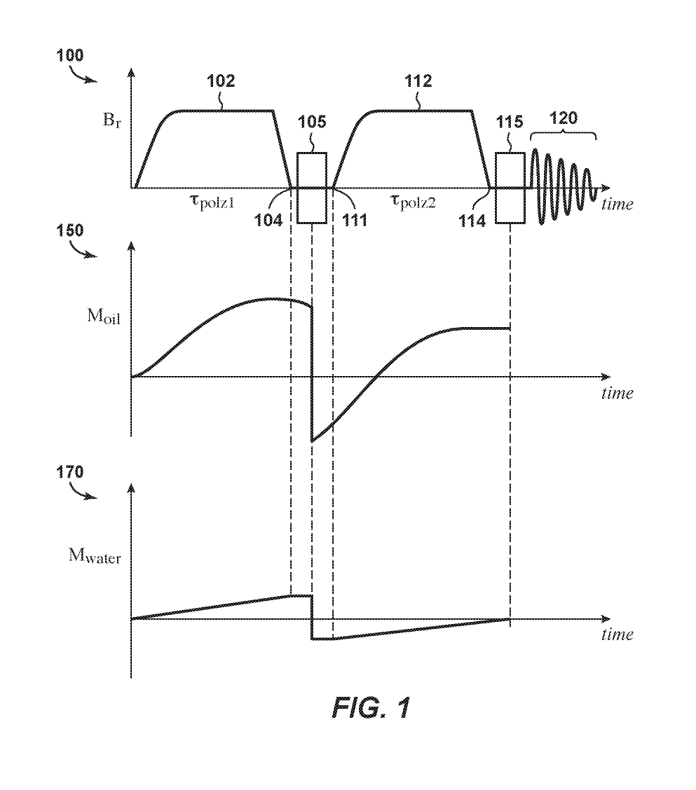

The term “adiabatic fast passage inversion sweep” as used herein refers to an adiabatic fast passage sweep that produces an inversion of the magnetization vector of material within the region of interest (to which the sweep is transmitted), resulting from varying the frequency of the RF signal during the sweep such that the frequencies are swept to the Larmor frequency; applying a 180-degree phase shift to the RF signal at substantially the Larmor resonance frequency to reverse direction of the sweep; and sweep the frequency back to the original value. After the phase shift, the sweep direction is opposite compared to before the phase shift. For example, the RF frequency at the start of the AFP sweep may begin at a higher frequency than the NMR Larmor frequency and the RF frequency is steadily decreased as the AFP excitation signal length increases. When the RF frequency becomes substantially equal to the NMR Larmor frequency, the RF phase shift is applied. Subsequent to the phase shift, the RF frequency steadily increases as the AFP signal length continues to decrease until the RF frequency reaches the initial maximum RF frequency at the end of the AFP sweep. The magnetization vector begins aligned with the +z direction (axis) (thermal equilibrium) and rotates through the transverse plane ending up aligned along the −z direction (axis). This results in an inversion. Paragraph [0050] and FIG. 1A of WIPO Publication WO 2015/084347, which description and illustration are incorporated by reference, illustrate an AFP inversion signal.

An “AFP inspection sweep” or “adiabatic fast passage inspection sweep” refers to an AFP signal that provides a sweep of frequencies resulting in tipping the magnetization vector of material in the region of interest (to which the AFP inspection sweep is directed) into the transverse (x,y) plane, and preferably such that it has substantially 0 magnitude in the z-direction.

The term “hard pulse” as used herein refers to a high power, short pulse (in time) at substantially the Larmor resonance frequency of the material to be detected. Hard pulses are preferably created by applying a high current of short duration at a single oscillatory frequency (e.g., the Larmor resonance frequency).

The term “hard inversion pulse” as used herein refers to a hard pulse that produces an inversion of the magnetization vector resulting from excitation occurring during the pulse of radio frequency (RF) signal at the Larmor resonance frequency. The magnetization vector begins aligned with the +z direction (axis) and rotates through the transverse plane ending up aligned along the −z direction (axis). This results in an inversion. Paragraph [0056] and FIG. 1B of WIPO Publication WO 2015/084347, which description and illustration are incorporated by reference, illustrate a hard inversion pulse.

The term “hard inspection pulse” as used herein refers to a hard pulse that follows an inversion excitation signal and provides a 90 degree rotation of the magnetization vector to orient with substantially zero z component of magnetization such that the vector lies within the transverse (x,y) plane.

The term “inversion” as used herein refers to a transformation of the magnetization from its thermal equilibrium state to a non-equilibrium state in which the magnetization vector is oriented 180 degrees (along the −z axis) from the static magnetic field (B₀) aligned along the +z direction.

“Larmor resonance frequency” or “Larmor frequency” refers to the term of art for the rate of precession of the magnetic moment of a proton around the z-axis in the static magnetic field B₀ having direction in the z-axis. This is approximately 2 kHz for protons in the Earth's magnetic field.

The term of art “T1 relaxation time” (also referred to as “spin lattice relaxation time” or “longitudinal relaxation”, or sometimes by the shorthand “T1”) as used herein refers to the period of time required for the magnetization vector of 63% of the excited nuclei to realign with the static magnetic field, B₀, after being nulled.

The term of art “T2 relaxation time” (also referred to as “spin relaxation” or “transverse relaxation”, or sometimes by the shorthand “T2”) as used herein refers to the period of time required for the excited nuclei to lose phase coherence (de-phase) among the nuclei spinning perpendicular to the static magnetic field, B₀, such that 37% of the original vector remains.

“Oil” as used herein can refer to any liquid petroleum material. Petroleum can be a very complex fluid in terms of NMR signals. As explained in Paragraphs [00105] and [00106], as well as FIG. 8, of WO 2015/084347, oil is generally comprised of a very large number of hydrocarbon molecules, which are each described by a characteristic NMR relaxation time, T₂ᵢ. In such complex molecules, relaxation times may be substantially the same for each molecule found in the fluid such that the substantially same relaxation time decay profile is observed. Thus, it is acceptable in such circumstances to treat the complex fluid as a single material for NMR signal purposes.

“Gas” as used herein may refer to any naturally occurring lighter hydrocarbon material (e.g., methane, ethane, propane, butane or other C₁ to C₄ hydrocarbons) often found in association with crude petroleum, and may include hydrocarbons in the liquid and/or gaseous state, such as natural gas, natural gas liquids, condensates, and the like.

“Water” as used herein may refer to seawater or freshwater, which may contain many other components (e.g., salt), or it may refer to more pure forms of water (e.g., distilled or pure water). The term “water” is not intended to be limited to any of these particular levels of purity (or impurity) unless expressly stated otherwise.

Obtaining NMR Measurements for Detecting One Material within Another

As described above, the present disclosure in many embodiments relates to methods, systems, and apparatuses for detecting a first material in the presence of a second material (i.e., determining whether the first material is also present within the second material), within a region of interest in the Earth and within a static magnetic field B₀. For instance, methods according to various embodiments include (I) acquiring a first nuclear magnetic resonance (NMR) measurement within the region of interest; and (II) determining the presence of the first material within the region of interest from the NMR measurement. Methods of some embodiments may include multiple NMR measurement acquisitions—for instance, some methods may further include (I-2) acquiring a second NMR measurement within the region of interest; (I-3) acquiring a third NMR measurement within the region of interest; and so on, with the determining (II) being based upon each of the one or more acquired NMR measurements.

As noted above, the methods described herein for acquiring the first NMR measurement include double pre-polarization. These double pre-polarization methods generally fall into one of two categories: (1) “double pre-polarization nulling” methods, utilizing the application of two pre-polarization currents with (a) a radio frequency (RF) inversion signal transmitted into the region of interest at a time between the two pre-polarizations and (b) a RF inspection signal transmitted into the region of interest after the second pre-polarization current at a time such that the magnetization vector M₂ of the second material is substantially 0 in the z-direction, nullifying the second material from the subsequently-acquired NMR signal; and (2) “double-acquisition nulling” methods, again utilizing two pre-polarization currents, but with an initial RF inspection signal interposed at a time between the two pre-polarizations (and, as with (1), the RF inspection signal transmitted after the second pre-polarization current). The “double-acquisition nulling” methods utilize different pre-polarization times τ_{polz1} and τ_{polz2} in combination with algebraic combination of the two acquired NMR signals to result in nullification of the second material's contribution to the combined NMR signal.

In various embodiments, then, the first material is a material of interest in the region of interest (e.g., a material the presence of which in the region of interest is desired to be determined) and the second material is a material for which at least a portion, and preferably substantially all, of the NMR signal is to be suppressed (e.g., at least 50% of the NMR signal may be suppressed, preferably at least 75%, at least 85%, at least 90%, at least 95%, or at least 99%). The region of interest may be under a surface of the Earth, and/or within a portion of a body of water, and located at least partially in a static magnetic field such as Earth's magnetic field or a magnetic field generated by man-made equipment. In one or more embodiments, the man-made equipment may be one or more additional coils configured to generate a static magnetic field in the region of interest or one or more magnets.

As noted above, the presently described techniques are particularly useful for detecting the presence of a first material within a second material, when the spin-lattice relaxation time (T1) of the first material is less than the T1 of the second material. For instance, the spin-lattice relaxation time T1 of oil is less than T1 of water. Typically, T1ₒᵢₗ is typically within the range from 1 to 100 ms, or several hundred ms (e.g., 200, 300, 400, or 500) (with very light oils, e.g., those having no metals, no aromatics, and limited hydrocarbon chain length, being on the lower end of this range). T1_{water}, on the other hand, is generally of the order of 1 second. T1 values depend upon the strength of the magnetic field; these values are reported for Earth's magnetic field—but these Earth field T1 values are essentially invariant to the relatively small change in the longitudinal field resulting from the application of the preferred pre-polarization fields Bₚₚ in accordance with various embodiments. Thus, in various embodiments described herein, τ_{polz1} and τ_{polz2} may each be between 1 ms and 1.5 sec, preferably between 100 ms and 900 ms, such as from a low of any one of 100, 150, 200, 250, 300, 350, and 400 ms to a high of any one of 300, 350, 400, 450, 500, 550, 600, 650, 700, 750, 800, 850, 900, and 950 ms, provided the high end of the range is greater than the low end of the range. Such selections are particularly useful in embodiments in which oil is the first material (i.e., the material the presence of which is to be determined) and water the second material, and the static magnetic field is earth's magnetic field.

Such embodiments could include, e.g., detecting a minor amount of oil in a major amount of water, such as in oil and gas exploration operations, or, in particular, in oil spill recovery operations. For instance, the techniques described herein could be particularly useful in detecting the presence of oil in water under ice; the presence of oil in water in a subsea or other underwater environment, or in other situations where visual inspection or other detection means are impractical. Thus, methods of various embodiments may include acquiring a NMR measurement from a portion of a body of water (e.g., freshwater or seawater), and, based on the acquired NMR measurement, determining whether oil is present in the portion of the body of water. Acquiring the NMR measurement may be carried out in accordance with the double pre-polarization methods previously noted. The portion of the body of water may in some embodiments be located under ice, or otherwise inaccessible for visual inspection.

The various techniques described herein may be utilized in detecting the presence of any first material in any second material, where the T1 of the first material is less than the T1 of the second material (allowing for selection of pre-polarization pulse times τ_{polz1} and τ_{polz2} between the T1 values of the two materials). Further, the presence of any one or more of multiple shorter-T1 materials may be detected by such methods, since the NMR signal of the longer-T1 second material is suppressed. For instance, methods according to the present disclosure may be utilized to detect a contaminant material in water (e.g., an organic contaminant material in water), and/or to detect a contaminant material in an organic bulk material.

In particular embodiments, there may be less, potentially substantially less, of the first material (and/or other lower-T1 materials) than the second material in the region of interest. For instance, the region of interest may comprise second material (e.g., water) and first material (e.g., a hydrocarbon such as oil and/or gas) at a weight ratio (second material: first material) within the range from a low end of any one of 1:1, 2:1, 3:1, 4:1, 5:1, 10:1, 15:1, or 20:1, to a high end of 5:1, 10:1, 15:1, 20:1, 25:1, 30:1, 35:1, 40:1, 45:1, 50:1, 60:1, 70:1, 80:1, 90:1, 99:1, 100:1, 200:1, 300:1, 400:1, 500:1, or even 1000:1.

Furthermore, many methods described herein are particularly useful in detecting fluid materials (oil in water, or other shorter-T1 fluid(s) in the presence of longer-T1 fluid), although these methods may also be applied to gels and/or solids where the T1 relaxation time differences between (i) target material to be detected and (ii) other material permit.

Each of the general methods of acquiring the NMR measurement (e.g., double pre-polarization nulling and double acquisition nulling) is described in more detail below.

### Double Pre-Polarization Nulling

For various methods in accordance with “double pre-polarization nulling” techniques, both the first and second materials' magnetizations within the region of interest are first exposed to a pre-polarization magnetic field (generated by applying a pre-polarization current) that is stronger than the static magnetic field B₀ (e.g., Earth's magnetic field). Such field will increase the magnetization of all fluids in response; however, the shorter-T1 material(s) will have faster rates of response as compared to longer-T1 materials. At an appropriate time after application of the pre-polarization field (e.g., at a time greater than the T1 relaxation time of the first material, and less than the T1 relaxation time of the second material), the first material's magnetization will have fully polarized while the magnetization of the second material will have developed only partially and may still be in the linear region of exponential growth. An RF inversion signal at this time would invert both materials' magnetization (e.g., from the +z to the −z direction), and the magnetization vector of the first material will have recovered fully, again (e.g., to the +z direction), after a period similar to the first interval mentioned above. The magnetization from the second material, on the other hand, would recover from its inverted orientation to approximately a null value (approximately 0 magnitude in the z-direction) in the same period. The lengths of time for application for each of the pre-polarization currents can be adjusted so the attainment of the null, mentioned above, would be complete. An RF inspection pulse at the point in time at which the second material's magnetization is null would induce an NMR signal that is exclusively from the first material (and/or any other lower-T1 material which may be present in the region of interest), while nulling the signal from the second material (e.g., majority material), providing a useful indicator of the presence of the first (and potentially other lower-T1) material in the presence of the second material, even where there is more, potentially even far more, of the second material than the first.

Thus, in various of these embodiments, acquiring the first NMR measurement may include: (a) applying a first pre-polarization current for a first period of time τ_{polz1} to generate a first additional magnetic field within the region of interest that is greater than the static magnetic field; (b) transmitting, after the applying (a), a first radio frequency (RF) signal into the region of interest, wherein the first RF signal is an RF inversion signal; (c) applying, after the transmitting (b), a second pre-polarization current for a second period of time τ_{polz2} to generate a second additional magnetic field within the region of interest that is greater than the static magnetic field; (d) transmitting, after the applying (c), a second radio frequency (RF) signal into the region of interest, wherein the second RF signal is an RF inspection signal. In such embodiments, T1 of the first material is less than T1 of the second material; and the first period of time τ_{polz1} and the second period of time τ_{polz2} are each greater than the T1 relaxation time of the first material and are each less than the T1 relaxation time of the second material. The first RF signal (the RF inversion signal) is preferably sufficient (e.g., it creates a magnetic field in the region of interest of strength and/or direction) to invert magnetization vectors of both the first and second material within the region of interest such that the net magnetization vector of the protons of the first and second material are each substantially aligned with the negative (−) z axis (where the direction of the static magnetic field B₀ is referenced to the z axis). The second RF signal (the RF inspection signal) preferably generates an NMR signal from the region of interest, for example by the mechanism of tipping the magnetization vector M₁ of the first material, if present, into the transverse (x,y) plane with respect to the direction (z) of the static magnetic field B₀.

FIG. 1 illustrates a stylized timing diagram 100 (showing the generated magnetic field strength, Bᵣ, in the region of interest as a function of time) for methods in accordance with these embodiments. Bᵣ represents a magnetic field signal, which is either an input (e.g., as may be generated in the region of interest by an RF signal such as an RF inversion or RF inspection signal) or output (e.g., FID signal generated by precession), depending on the position along the x-axis, as further described below. FIG. 1 also includes a stylized graph 150 of the expected magnitude of the magnetization vector Mₒᵢₗ of the first material (as illustrated in FIG. 1, oil) in the z-direction and a graph 170 of the expected magnitude of the magnetization vector M_{water} of the second material (as illustrated in FIG. 1, water) in the z-direction, in response to the currents and signals generated per the timing diagram 100. As with all illustrative cases discussed herein, it is assumed that the static magnetic field B₀ is in the z-direction for reference. Further, as noted previously, T1 relaxation time of oil is significantly less than T1 relaxation time of water (e.g., approximately 10 times less, depending, as noted previously, on how light or heavy the oil constituents are, and/or presence of aromatics, metals, and other contents of the oil).

As shown in FIG. 1, the first pre-polarization current 102 is applied over the first pre-polarization time τ_{polz1}, after which the first RF signal (RF inversion signal 105) is transmitted.

The graph 150 shows the faster response of the oil's magnetization vector Mₒᵢₗ in the z direction, becoming fully polarized before the end of τ_{polz1} (104); while the graph 170 shows the slower response of the water's magnetization vector M_{water} in the z direction, such that it is still evolving (and approximately in the linear region of exponential growth) at the end of τ_{polz1} (104).

The RF inversion signal 105 inverts both magnetization vectors, leaving Mₒᵢₗ at a much greater (negative) magnitude than M_{water}. RF inversion signal 105 is shown in FIG. 1 as a hard inversion pulse, although it will be appreciated that an adiabatic inversion sweep could instead be utilized for the RF inversion signal 105.

Following the inversion pulse 105, the second pre-polarization current 112 is applied for time τ_{polz2}, ending at point of time 114. The graph 150 again shows the much faster response of oil's magnetization vector Mₒᵢₗ to the pre-polarization current 112, quickly returning to the +z magnitude.

As noted, oil, having shorter T1 relaxation time, would be expected to recover its equilibrium magnetization vector (i.e., a +z vector) more quickly than water. However, this phenomenon is enhanced by the second pre-polarization current (creating the second pre-polarization magnetic field Bₚₚ₂), which serves to accelerate the recovery of the shorter-T1 first material (oil) to the +z direction to a much greater degree than the recovery of the longer-T1 second material (water).

As illustrated in FIG. 1, τ_{polz2} is substantially equal to τ_{polz1}. This advantageously results in the water's magnetization vector M_{water} returning to the null point at the end 114 of the application of the pre-polarization current 112. This makes it a simple matter to time the RF inspection signal (here, hard inspection pulse 115) to be transmitted upon termination 114 of the second pre-polarization current, thereby insuring the hard inspection pulse 115 occurs at the point of time 114 when the magnetization vector M_{water} of the water has magnitude in the z-direction of 0, i.e., it is nulled. The inspection pulse 115 perturbs the magnetization vector Mₒᵢₗ of the oil only, since the magnetization vector M_{water} of the water is null; thus only the Mₒᵢₗ is tipped into the transverse (x,y) plane, and only the Mₒᵢₗ precesses as it returns to equilibrium (the +z direction), such that the NMR signal received (shown as FID signal 120 in FIG. 1) has substantially no contribution from the water (or other second material with greater T1 relaxation time).

Moreover, according to some embodiments, given the weakness of the static magnetic field B₀ (e.g., when the static magnetic field is Earth's magnetic field), it can be approximated that M₂ of the second material (e.g., M_{water} where water is the second material) will grow only when the pre-polarization current is applied (provided that less than half, preferably less than one fourth, of the τ_{polz1} time has elapsed between the end 104 of the first pre-polarization current 102 and the beginning 111 of the second pre-polarization current 112. In methods according to such embodiments, then, this provides an additional reason to select τ_{polz2} to be of roughly equal length to τ_{polz1}, because application of pre-polarization current over the same length of time that generated the initial excitation (now inverted) will result in nullification of the magnetization vector. Therefore, in some advantageous embodiments, 0.99<τ_{polz1} τ_{polz2}<1.01, preferably 0.999<τ_{polz1}<τ_{polz2}<1.001, and even more preferably τ_{polz1}=τ_{polz2}.

Further, in these and other embodiments, the first and second pre-polarization currents are preferably otherwise the same (i.e., identical in all respects other than, or in addition to, duration τ), such that the strength of the generated pre-polarization magnetic fields Bₚₚ₁ and Bₚₚ₂ are the same. However, the ordinarily skilled artisan with the benefit of this disclosure will readily appreciate that the field strengths and/or time of current application could be varied, so long as the desired effect (nullification of the M₂ vector after the second pre-polarization current is applied) is achieved.

As also shown in FIG. 1, the double pre-polarization method further advantageously boosts the magnitude in the z-direction of the magnetization vector M₁ of the first material, if present, more quickly than would occur by waiting on the natural restoration to equilibrium. This provides (a) better signal-to-noise ratio at the point of time of the RF inspection signal (e.g., hard inspection pulse 115) and (b) less wait time to transmit the RF inspection signal (e.g., hard pulse 115), which can be particularly important in utilizing NMR techniques for detecting materials in field situations. For instance, where the double pre-polarization technique is used for detection of oil in water, particularly in an oil spill response situation, quick acquisition (e.g., on the order of minutes instead of hours or days) can provide crucial advantages over other detection techniques.

Accordingly, in some embodiments, the acquisition of the first NMR measurement within the region of interest takes place in less than 10, preferably less than 7, less than 6, less than 5, less than 4, or even less than 3, minutes.

Advantageously, methods in accordance with these embodiments result in nulling the second material (e.g., water)'s signal. This means that minority species (including oil, but also including possibly other minority species) may be detected by analyzing the NMR signal, so long as those minority species have T1 relaxation times less than the majority species. That is, more than one minority material may be detected in this manner, which both suppresses the NMR signal of the majority material (with longer T1 relaxation time) and enhances the signal-to-noise ratio of the shorter-T1 species.

Further, methods according to these and other embodiments may be carried out by creating the pre-polarization magnetic field using a coil or other device remotely located from the region of interest (i.e., where the first and second materials (oil and water, respectively, per FIG. 1) are located). One example of such remote location is for an antenna transmit and receive coil located at the surface of the earth.

The time-dependent pre-polarization magnetic fields of these and other embodiments may each be created by applying a non-oscillatory electric current to the coil. The inversion and inspection signals, on the other hand, are transmitted by applying oscillatory electric current into an antenna transmit/receive coil. The oscillation frequency of the applied current is adjusted to correspond to the NMR Larmor frequency, which, as is known in the art, depends on the gyromagnetic ratio for a specific nucleus and on the magnetic field at the material location.

In some embodiments, adiabatic fast passage (AFP) inversion and/or inspection signals may be preferred to hard pulses. This is particularly the case in situations where the magnetic field generated by the signal generation equipment (e.g., antenna transmit/receive coil) is substantially non-uniform at the material of interest. In such cases, the NMR signal sensitivity is also substantially non-uniform across the material that is located at a spread of distances from the antenna transmit/receive coil or other signal generation equipment. Thus, AFP methods for signal generation may have the ability to maximize the NMR signal from material located at a distribution of distances from the coil.

### Double-Acquisition Nulling

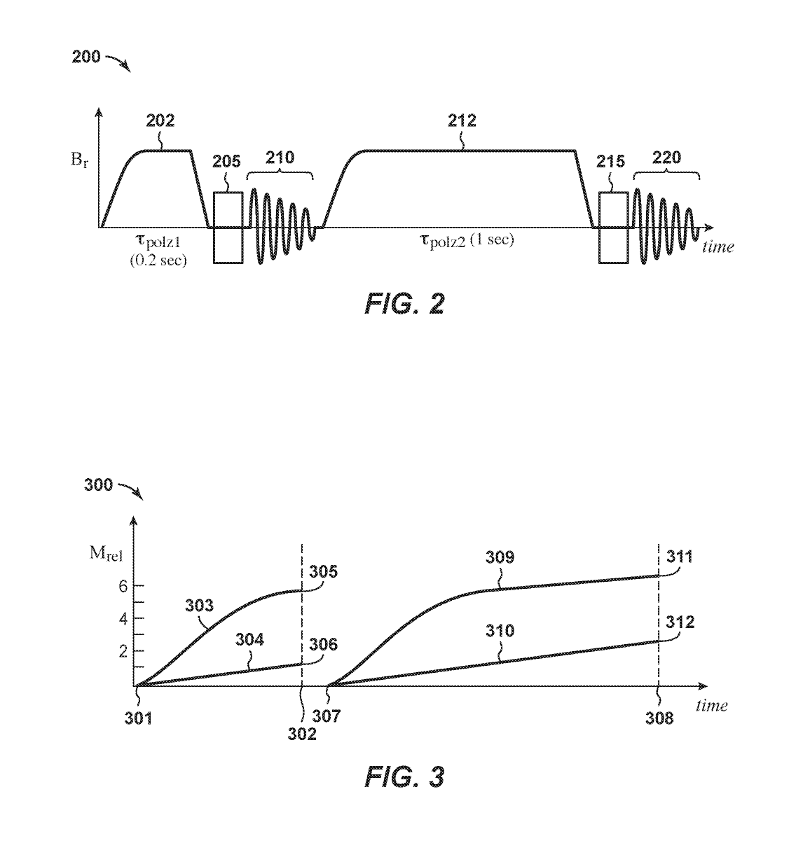

As illustrated in FIG. 2 (a stylized timing chart 200 showing the generated magnetic field strength, Bₚₚ, in the region of interest as a function of time) in methods in accordance with the “double-acquisition nulling” technique, the pre-polarization currents 202 and 212 are again applied twice, but for unequal durations (i.e., such that the first pre-polarization time τ_{polz1} is less than the second pre-polarization time τ_{polz2}). That is, the first and second pre-polarization magnetic fields Bₚₚ₁ and Bₚₚ₂ are generated for different durations in the region of interest. In particular, in FIG. 2, τ_{polz2} is 1.0 seconds and τ_{polz1} is 0.2 seconds, such that τ_{polz2}=5*τ_{polz1}.

A first RF inspection signal 205 is transmitted after the first pre-polarization current 202 is applied, which leads to perturbation and precession generating the first NMR signal 210 (shown as a FID signal 210 received after the inspection signal 205 in FIG. 2). The RF inspection signal can be a traditional “hard pulse” or, e.g., an AFP inspection sweep as described elsewhere in this application, or any other suitable inspection signal. A second RF inspection signal 215 follows the second pre-polarization current 212, generating a second NMR signal 220 (shown as a FID signal 220 received after the second inspection signal 215 in FIG. 2). Again, this second RF inspection signal can be a hard pulse, or, e.g., an AFP inspection sweep, or any other suitable inspection signal. Each NMR signal 210 and 215 acquired comprises (a) the signal from the first material (in FIG. 2, oil) combined with (b) the signal from the second material (in FIG. 2, water).

These signals 210 and 215 are then algebraically combined to eliminate the (b) signal from the second material (water). For instance, the following exemplary discussion illustrates how the two signals may be algebraically combined to eliminate the second material (water)'s signal.

First, the first NMR signal S₁ and the second NMR signal S₂ may each be presented or considered as the sum of first and second materials' signals in the region of interest (keeping with the example of FIG. 2, these signals are shown in Equations (1) and (2) below as Sₒᵢₗ (first material) and S_{water} (second material)). Further, since both signals S₁ and S₂ are obtained from the same region of interest, both signals are taken to be composed of the same constituent signals (i.e., both acquired NMR signals S₁ and S₂ are composed of the same signals from the same material in the region of interest).

S₁=Sₒᵢₗ+(τ_{polz1}/T1_{water})*S_{water} (1)

S₂=Sₒᵢₗ+(τ_{polz2}/T1_{water})*S_{water} (2)

Second, as also shown in Equations (1) and (2), the signal from the second material (water) in each equation is assigned a modifying ratio (τ_{polz,i}/T1_{water}), where i is the number of the pre-polarization current time corresponding to the following generated NMR signal (e.g., i is 1 for the first pre-polarization time following which the first signal S₁ was obtained). This is because the first and second pre-polarization times τ_{polz1} and τ_{polz2} were chosen to be greater than the T1 relaxation time of the first material (oil) and less than the T1 relaxation time of the second material (water); it can therefore be deduced that the first material (oil) is fully relaxed in both signals, whereas the water was still in the linear region of evolving magnetization vector response at the time each signal was acquired. From this, one can conclude that the signal for the second material (for water, S_{water}) in each of Equations (1) and (2) is actually just a fraction of the expected signal were the second material (water) to be fully relaxed, like the first material (oil)—which would occur if the corresponding pre-polarization time τ_{polz} were equal to the T1 of water. Thus, the modifying ratio (τ_{polz,i}/T1_{water}) is assigned to the second material (water) in each signal Sᵢ equation.

Third, because the relationship between τ_{polz1} and τ_{polz2} is known (because each is selected in the NMR signal generation method in embodiments in accordance with FIG. 2), τ_{polz2} is re-characterized in terms of τ_{polz1} (or vice-versa, if desired). In accordance with the exemplary discussion corresponding to FIG. 2, τ_{polz2}=5*τ_{polz1}. Equations (3) and (4) illustrate the updated signal equations for S₁ and S₂ in accordance with FIG. 2 with this re-characterization.

S₁=Sₒᵢₗ+(τ_{polz1}/T1_{water})*S_{water} (3)

S₂=Sₒᵢₗ+(5*τ_{polz1}/T1_{water})*S_{water} (4)

Fourth, the second signal S₂ is scaled down to match the first signal S₁ on the basis of the difference in pre-polarization times (or, the first signal is scaled up to match the second signal S₂). That is, because τ_{polz2} is 5 times τ_{polz1} per the FIG. 2 example, S₂ is 5 times the intensity of S₁. The signals can be scaled to eliminate this difference by either multiplying S₂ by ⅕ or multiplying S₁ by 5.

Fifth, the signal and scaled-signal pair are subtracted from one another (smaller value subtracted from larger, post-scaling).

Equation (5) below shows scaling the second signal S₂ down (by ⅕ in this case, to match the ratio τ_{polz1}/τ_{polz2} accounting for the weighted differences in signal intensity from S₁ to S₂) and subtracting the scaled-down S₂ from S₁, with substitution of the values from Equations (3) and (4).

S₁−(⅕)S₂=Sₒᵢₗ+(τ_{polz1}/T1_{water}*S_{water}−(⅕)ₒᵢₗ−⅕*τ_{polz1}/T1_{water})*S_{water} (5)

Equation (6) below shows the simplification of Equation (5) to arrive at the writing of the two received signals S₁ and S₂ in terms of only the component arising from the second material (Sₒᵢₗ for oil in accordance with FIG. 2), by combining the two Sₒᵢₗ terms and the two S_{water} terms (which results in zeroing out the S_{water} term).

S₁−(⅕)S₂=(⅘)Sₒᵢₗ+[(τ_{polz1}−(⅕)*5*τ_{polz1})/T1_{water}]*S_{water}=(⅘)Sₒᵢₗ+0=(⅘)Sₒᵢₗ (6)

Algebraic combinations according to such embodiments may be referred to as signal scaling and subtraction. We further note that, where the region of interest is being analyzed for the presence of any one of multiple lower-T1 materials, the “Sₒᵢₗ” (or, in more general embodiments, S_{1st Material}) can simply be considered as the aggregate NMR signal for any one or more lower-T1 materials of interest; the desired end result of eliminating the NMR signal from the second (majority) material will still be obtained, and the remaining NMR signal will be in terms of the component(s) of interest, if any—such that any remaining signal after signal scaling and subtraction would indicate the presence of the material(s) of interest.

FIG. 3 provides a stylized illustration of the operation of signal scaling and subtraction (300). FIG. 3 is a stylized illustration of the time-dependent evolution of magnetization for first material (303 and 309) following first pre-polarization 301 and second pre-polarization 307, respectively; and evolution of magnetization for second material (304 and 310) following the first pre-polarization 301 and second pre-polarization 307, respectively.

The relative magnitudes Mᵣₑ₁ of magnetization vectors of the first material and second material (305 and 306, respectively) following first pre-polarization period τ_{polz1} are illustrated in this stylized example as being equal to 5 and 1, respectively; these magnetizations would translate to a first NMR signal obtained following an RF inspection signal applied at time 302 (in FIG. 3) following the first pre-polarization period τ_{polz1}.

Likewise, the magnitudes of magnetization vectors of the first and second material (311 and 312, respectively) are shown to be 6 and 3 following the second, longer, pre-polarization period τpolz2. These magnetizations would translate to a stronger second NMR signal received after an inspection signal 308 is transmitted into the region of interest following the second pre-polarization period τ_{polz2}, proportional to the ratio of magnitudes of magnetization 311 and 312 as compared to the respective magnitudes of magnetization 305 and 306 resulting from the first pre-polarization. This phenomenon occurs because the magnetization from the first material, which has a short T1, does not increase very much by increasing the pre-polarization period from τ_{polz1} to τ_{polz2}, since the first material is nearly fully relaxed (recovered to full value of magnetization after starting from zero) in both periods. However, the slow-relaxing magnetization of the second material continues to relax nearly linearly as the pre-polarization period is increased to τ_{polz2} in the second pre-polarization. Therefore, the ratios of the two components are different at the ends of the two pre-polarization periods, allowing for the scaling and subtraction method of algebraic combination to effectively null out the NMR signal from the second, slower-relaxing, material.

In particular, similar to the above description with respect to FIG. 2, the first NMR signal (received from materials with magnetizations of relative magnitude M equal to 5 and 1, as noted) can be scaled-up so that the second material's smaller magnetization magnitude from the first NMR signal (i.e., 1) matches the second material's magnitude in the second signal (i.e., 3). This results in scaled magnitudes of 15 and 3 for the first and second material, respectively.

Subtracting the second signal set from the scaled first signal set (i.e., subtract 6 and 3 respectively from 15 and 3) yields a magnetization value from the first material of 15-6=9, and a magnetization value of 0 from the second material.

### Systems and Equipment

The above-described techniques may be implemented using any systems and equipment suitable for (a) applying pre-polarization currents so as to generate a magnetic field in a region of interest, (b) transmitting RF inversion and inspection signals into the region of interest, and (c) receiving any NMR signal from the region of interest.

Examples of such systems and equipment are described throughout WIPO Publication WO 2015/084347. For instance, embodiments of the present disclosure include implementation through an NMR tool such as those including a coil, designed and utilized as described, e.g., in Paragraphs [0072]-[0078] and [0080] of WO 2015/084347, which description is incorporated by reference herein. Suitable coils include loop coils, flat coils and/or flat coil arrays, with or without substrate bodies and/or electrically conducting plates and other like features, designed and utilized as described in Paragraphs [0081]-[0102] and FIGS. 3-7 and 20 of WO 2015/084347, which description is also incorporated by reference herein.

Further, methods and systems of the present disclosure may include implementation via helicopter or other system as described in Paragraphs [0143]-[0147] and FIGS. 17 and 18 of WO 2015/084347, which description is also incorporated by reference herein.

### EXAMPLES

### Example 1

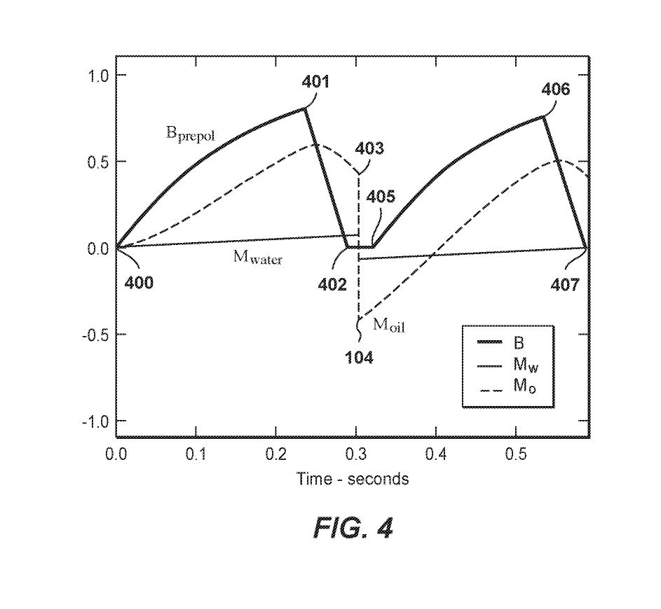

This example illustrates double pre-polarization nulling methods in accordance with some embodiments. FIG. 4 is a stylized timing chart illustrating the response of the longitudinal magnetization, Mₒᵢₗ and M_{water}, for the data acquisition timing sequence described in connection with some embodiments of double pre-polarization nulling (e.g. as shown in FIG. 1). The longitudinal magnetization responses shown in FIG. 4 are for representative fluids, canola oil and water (equal portions of each), which respectively have shorter and longer spin-lattice (T1) relaxation times. The thick line labeled “Bₚᵣₑₚₒₗ” shows the current in the pre-polarization coils increasing smoothly from time 400 to time 401 (with reference to the x-axis of FIG. 4, approximately t=0 seconds and t=0.25 seconds, respectively). During this time period, the longitudinal magnetization (dashed line labeled “Mₒᵢₗ” in FIG. 4) of the canola oil, increases rapidly while the longitudinal magnetization (solid line labeled “M_{water}^{”} in FIG. 4) of the water increases more slowly. This is a direct consequence of the differences in the T1 values of the canola oil and water.

During the time interval between points of time 401 and 402 (approximately t=0.25 seconds to 0.29 seconds), the current in the pre-polarization coils is rapidly reduced. The corresponding rapid reduction in the pre-polarization magnetic field is observed as a decrease in the longitudinal magnetization of the canola oil (Mₒᵢₗ). No current is applied to the pre-polarization coils between points of time 402 and 405 (approximately t=0.29 seconds to t=0.31 seconds).

At point of time 403 (slightly before t=0.30 seconds), an RF inversion pulse (not shown in FIG. 4) is applied. This results in the inversion of the longitudinal magnetization for both the water and the canola oil. At point of time 404 (just after t=0.30 seconds), the longitudinal magnetization of the canola oil (Mₒᵢₗ) has relative value (with reference to the y-axis of FIG. 4) of approximately −0.5, while the longitudinal magnetization of the canola oil prior to the RF inversion pulse had relative value of approximately +0.5. In contrast, the relative change in the longitudinal magnetization for the water (M_{water}), approximately +0.05 to approximately −0.05, is very small relative to that of the oil.

At point of time 405 (approximately t=0.31 seconds), current is again applied to the pre-polarization coils, until point of time 406 (approximately t=0.55 seconds). In response to this pre-polarization magnetic field created in the region of the sample, the longitudinal magnetization of both the oil and water increase. However, because of the differences in the T1 values for the oil and water, the rate of increase in the value of Mₒᵢₗ is much faster than for M_{water}. At point of time 406, current is rapidly withdrawn from the pre-polarization coils, and current has decreased to 0 by point of time 407 (approximately t=0.60 seconds). Also at point of time 407, the magnetization for the oil, Mₒᵢₗ, is large, while the magnetization for the water, M_{water}, is zero. Thus, the NMR signal from the water has been suppressed and the only NMR signal observed upon transmission of an RF inspection signal (not shown in FIG. 4) at point of time 407 is from the oil.

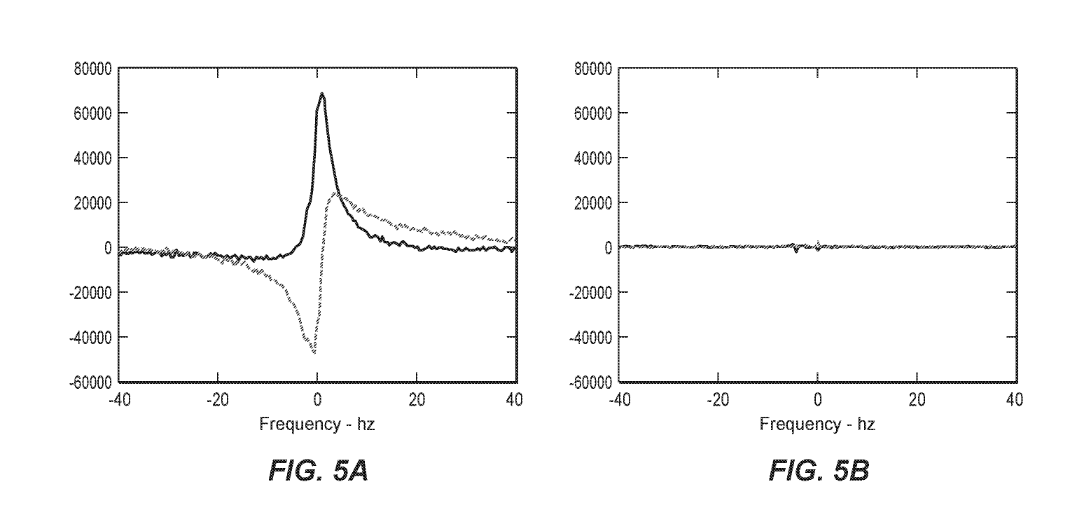

FIGS. 5A and 5B show the NMR spectrum acquired for a sample comprised of canola oil and water located near the NMR measurement coil using the double pre-polarization nulling method described above in connection with FIG. 4. FIG. 5A is the NMR spectrum observed for a sample comprise of two fluids: ˜70 pounds of canola oil and ˜70 pounds of water lying on a flat tray about 2 cm above the NMR coil. The NMR signals (“spectra”) shown in FIG. 5A are the in-phase and out-of-phase Fourier Transforms of the Free Induction Decay (FID) NMR signals measured during the time following time period 407 (e.g., corresponding to the time period 120 in the illustration of FIG. 1). Four FID signals were acquired and by repeating the double pre-polarization timing sequence shown in FIG. 4 four times. The sum of the four in-phase and out-of-phase FID signals acquired were Fourier Transformed and shown in FIG. 5A. Hard RF pulses were applied to suppress the NMR signal from the water in FIG. 5A.

FIG. 5B shows the NMR spectrum acquired from the water sample after the canola oil was removed, i.e., the NMR spectrum shown in FIG. 5B was obtained using the same NMR data acquisition timing sequence used to obtain the NMR spectrum shown in FIG. 5A, and with the same amount of water present as was present for obtaining the NMR spectrum shown in FIG. 5A.

FIGS. 5A and 5B serve to illustrate two aspects of this method. First is the significant increase in the NMR signal intensity obtained by the increase in the longitudinal magnetization using pre-polarization. The larger NMR signal intensity requires a significantly shorter time for data acquisition. The second feature illustrated is the effectiveness of the suppression of the NMR signal from the water using the method.

### Example 2

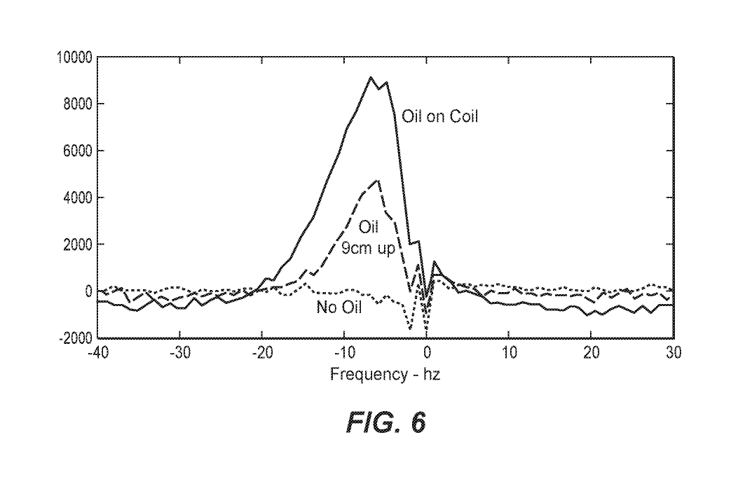

The NMR spectra shown in FIG. 6 were acquired using a method in accordance with the “double acquisition” methods described herein. The timing sequence of this method is per that illustrated in FIG. 2. The sample used for collecting the NMR data shown in FIG. 6 was comprised of approximately 150 pounds of water and 35 pounds of canola oil. The two fluids were placed in trays and the trays were positioned at various distances above the NMR coil, which was a 60 cm diameter audio Double-D coil made of #12 AQG copper wire. Each single-D was 3 twelve-turn coils in parallel. The two sides were connected in series. The coil had inductance L=0.315 mH and was resonated with about 25 μF. The driving voltage was 5 V peak and the driving current estimated to be about 1 A peak, such that at 6 cm, the magnetic field B₁ in the rotating frame at the sample location was about 215 mG. An additional pre-polarization coil was used, having diameter 70 cm, 70 turns, and was driven by 22 V (or about 70 A). At the center of the pre-polarization coil, the B_{PP} was 80 G.

The pre-polarization coil was used to apply a first pre-polarization current for 200 ms; transmit a first hard inspection pulse; and receive a first NMR signal from the canola oil/water mixture. Then, a second pre-polarization current was applied for 1 s; a second hard inspection pulse (identical to the first) was transmitted; and a second NMR signal received from the canola oil/water mixture. The two NMR signals were algebraically combined by scaling and subtraction as described hereinabove, creating the spectrum “Oil on coil” illustrated in FIG. 6. As shown in FIG. 6, a single strong peak results.

The NMR experiment was repeated with the same pre-polarization currents and inspection pulse currents and timings, but with the coil moved 9 cm away from the canola oil. The resultant spectrum is shown in FIG. 6 as “Oil 9 cm up.” As can be seen in FIG. 6, the single peak remained—it was still quite noticeable, although weaker in intensity.

Finally, the experiment was repeated again, but with the canola oil removed from the mixture. The resultant signal is shown as the “No oil” spectrum on FIG. 6. As is apparent, the major peaks present in the “Oil on coil” and “Oil 9 cm up” experiments have disappeared, confirming that the methodology successfully suppressed the water signal, allowing for identification of oil (when present).

While the present invention has been described and illustrated by reference to particular embodiments, those of ordinary skill in the art will appreciate that the invention lends itself to variations not necessarily illustrated herein. For this reason, then, reference should be made solely to the appended claims for purposes of determining the true scope of the present invention. All documents described herein are incorporated by reference herein, including any priority documents and/or testing procedures to the extent they are not inconsistent with this text. Likewise, the term “comprising” is considered synonymous with the term “including.” Whenever a composition, an element or a group of elements is preceded with the transitional phrase “comprising,” it is understood that—unless the context plainly dictates otherwise—we also contemplate the same composition or group of elements with transitional phrases “consisting essentially of,” “consisting of,” “selected from the group of consisting of,” or “is” preceding the recitation of the composition, element, or elements and vice versa.

We claim:

1. A method of detecting a first material in the presence of a second material within a region of interest in the Earth and within a static magnetic field B₀ with direction referenced to a z-axis, the method comprising:
(I) acquiring a first nuclear magnetic resonance (NMR) measurement within the region of interest, said acquiring (I) including:
(a) applying a first pre-polarization current for a first period of time τ_{polz1} to generate within the region of interest a first additional magnetic field Bₚₚ₁ that is greater than the static magnetic field B₀;
(b) transmitting, after the applying (a), a first radio frequency (RF) signal into the region of interest;
(c) applying, after the transmitting (b), a second pre-polarization current for a second period of time τ_{polz2} to generate within the region of interest a second additional magnetic field Bₚₚ₂ that is greater than the static magnetic field B₀;
(d) transmitting, after the applying (c), a second RF signal into the region of interest; and
(e) receiving an NMR signal from the region of interest; and
(II) determining the presence of the first material within the region of interest from the NMR measurement as a first result;
wherein:
the T1 relaxation time of the first material is less than the T1 relaxation time of the second material;
τ_{polz1} and τ_{polz2} are each (i) greater than the T1 relaxation time of the first material and (ii) less than the T1 relaxation time of the second material; and
the second RF signal is an RF inspection signal that generates an NMR signal from the region of interest.

2. The method of claim 1, wherein:
the first RF signal is an RF inversion signal that inverts the magnetization vector M₁ of the first material, if present, and the magnetization vector M₂ of the second material within the region of interest, such that said magnetization vectors M₁ and M₂ invert from the positive (+) z direction to the negative (−) z direction.

3. The method of claim 2, wherein the second RF signal is transmitted into the region of interest at a time when the magnetization vector M₂ of the second material is substantially zero along the z-axis

4. The method of claim 2, wherein 0.999<τ_{polz1}/τ_{polz2}<1.001.

5. The method of claim 4, wherein τ_{polz1}=τ_{polz2}.

6. The method of claim 2, wherein the first RF signal is an adiabatic fast passage inversion sweep.

7. The method of claim 2, wherein the first RF signal is a hard inversion pulse.

8. The method of claim 2, wherein the second RF signal is an adiabatic fast passage inversion sweep.

9. The method of claim 2, wherein the second RF signal is a hard inversion pulse.

10. The method of claim 1, wherein:
the first RF signal is an initial RF inspection signal that, when transmitted, generates an initial temporary transverse magnetic field B_{1,i} in the region of interest so as to tip the magnetization vector M₁ of the first material, if present, and the magnetization vector M₂ of the second material into the transverse (x,y) plane with respect to the direction (z) of the static magnetic field B₀;
the second RF signal additionally tips the magnetization vector M₂ of the second material into the transverse (x,y) plane with respect to the direction (z) of the static magnetic field B₀;
τ_{polz1} is less than τ_{polz2}; and
further wherein (I) acquiring the first NMR measurement further comprises:
(b-1) receiving, after the transmitting (b) and before the transmitting (d), an initial NMR signal from the region of interest; and
(f) algebraically combining the initial NMR signal received in (b-1) and the NMR signal received in (e) so as to nullify any contribution to the NMR signal from the second material.

11. The method of claim 10, wherein τ_{polz2} is within the range between 3*τ_{polz1} and 7*τ_{polz1}.

12. The method of claim 10, wherein the first RF signal and the second RF signal are each an adiabatic fast passage inspection sweep

13. The method of claim 10, wherein the first RF signal and the second RF signal are each a hard inspection pulse.

14. The method of claim 10, wherein (I) acquiring the first NMR measurement within the region of interest takes place in less than 5 minutes.

15. The method of claim 10, wherein the first material is oil and the second material is water.

16. The method of claim 10, wherein τ_{polz1} and τ_{polz2} are each greater than 100 ms and less than 1 s.

17. The method of claim 16, wherein τ_{polz1} and τ_{polz2} are each greater than 200 ms and less than 900 ms.

18. A method comprising:
(I) acquiring a NMR measurement from a portion of a body of water within Earth's magnetic field B₀, said acquiring (I) including:
(a) applying a first pre-polarization current for a first period of time τ_{polz1} to generate within the portion of the body of water a first additional magnetic field Bₚₚ₁ that is greater than the Earth's magnetic field B₀;
(b) transmitting, after the applying (a), a first radio frequency (RF) signal into the portion of the body of water;
(c) applying, after the transmitting (b), a second pre-polarization current for a second period of time τ_{polz2} to generate within the portion of the body of water a second additional magnetic field Bₚₚ₂ that is greater than the Earth's magnetic field B₀;
(d) transmitting, after the applying (c), a second RF signal into the portion of the body of water; and
(e) receiving an NMR signal from the portion of the body of water; and
(II) based at least in part on the acquired NMR measurement, determining whether oil is present in the portion of the body of water;
wherein τ_{polz1} and τ_{polz2} are each between 100 ms and 1 s.

19. The method of claim 18, wherein:
the first RF signal is an RF inversion signal that inverts the magnetization vector Mₒᵢₗ of the oil, if present, and the magnetization vector M_{water} of the water within the portion of the body of water, such that said magnetization vectors Mₒᵢₗ and M_{water} invert from the positive (+) z direction to the negative (−) z direction; and
the second RF signal is an RF inspection signal that, when transmitted, generates a temporary transverse magnetic field B₁ in the portion of the body of water so as to tip the magnetization vector Mₒᵢₗ of the oil, if present, into the transverse (x,y) plane with respect to the direction (z) of the Earth's magnetic field B₀.

20. The method of claim 18, wherein:
the first RF signal is an first RF inspection signal that, when transmitted, generates a first temporary transverse magnetic field B₁ in the portion of the body of water so as to tip the magnetization vector Mₒᵢₗ of the oil, if present, and the magnetization vector M_{water} of the water into the transverse (x,y) plane with respect to the direction (z) of the Earth's magnetic field B₀;
the second RF signal is a second RF inspection signal that, when transmitted, generates a second temporary transverse magnetic field B₁′ in the portion of the body of water so as to tip the magnetization vector Mₒᵢₗ of the oil, if present, into the transverse (x,y) plane with respect to the direction (z) of the Earth's magnetic field B₀;
τ_{polz1} is less than τ_{polz2}; and
further wherein (I) acquiring the NMR measurement further comprises:
(b-1) receiving, after the transmitting (b) and before the transmitting (d), an initial NMR signal from the region of interest; and
(f) algebraically combining the initial NMR signal received in (b-1) and the NMR signal received in (e) so as to nullify any contribution to the NMR signal from the water.
